(19) United States
(12) Patent Application Publication
(10) Pub. No.: US 2023/0057708 A1
(43) Pub. Date: Feb. 23, 2023

(54) SEMICONDUCTOR DEVICE, AND DATA PROCESSING CIRCUIT AND METHOD

(71) Applicant: CHANGXIN MEMORY TECHNOLOGIES, INC., Hefei (CN)

(72) Inventor: Enpeng GAO, Hefei (CN)

(21) Appl. No.: 17/952,258

(22) Filed: Sep. 25, 2022

Related U.S. Application Data
(63) Continuation of application No. PCT/CN2022/106162, filed on Jul. 18, 2022.

(30) Foreign Application Priority Data
Jun. 24, 2022 (CN) 202210726496.5

(51) Int. Cl. G11C 7/10; G11C 7/22

(52) U.S. Cl. CPC G11C 7/109; G11C 7/106; G11C 7/222; G11C 7/1066

(57) ABSTRACT

Embodiments provide a semiconductor device, and a data processing circuit and method. A chip select signal and a plurality of command signals are received through an input terminal of the data processing circuit, and a sampling signal is obtained by a receiver based on a clock signal. The chip select signal and the plurality of command signals are sampled by a latch based on the sampling signal to obtain an internal select signal and an internal command signal. The command decoder decodes the internal select signal and the internal command signal to obtain a data manipulation command.

### CROSS-REFERENCE TO RELATED APPLICATION

The present disclosure is a continuation of PCT/CN2022/106162, filed on Jul. 18, 2022, which claims priority to Chinese Patent Application No. 202210726496.5 titled “SEMICONDUCTOR DEVICE, AND DATA PROCESSING CIRCUIT AND METHOD” and filed to the State Intellectual Property Office on Jun. 24, 2022, the entire contents of which are incorporated herein by reference.

### TECHNICAL FIELD

The present disclosure relates to the field of semiconductor technology, and more particularly, to a semiconductor device, and a data processing circuit and method.

### BACKGROUND

Low Power Double Data Rate (LPDDR) is a communication standard for semiconductor devices. In the semiconductor devices using standards such as LPDDR5, a data processing circuit may receive an input command signal within one cycle of a clock signal, and decode the received input command signal to obtain a data manipulation command. How the data processing circuit in the semiconductor devices decodes the command signal to obtain the data manipulation command is a technical problem to be solved in the art.

### SUMMARY

The present disclosure provides a semiconductor device, and a data processing circuit and a method, such that the data processing circuit in the semiconductor device can decode a command signal to obtain a data manipulation instruction.

A first aspect of the present disclosure provides a data processing circuit, comprising: a plurality of input terminals, where the plurality of input terminals are configured to receive a plurality of command signals or a chip select signal, and the plurality of command signals received by different ones of the plurality of input terminals have different command bits; a receiver configured to receive a clock signal and obtain a sampling signal based on the clock signal; a latch connected to an output terminal of the receiver and the plurality of input terminals, where the latch is configured to receive the chip select signal and the plurality of command signals, and sample the chip select signal and the plurality of command signals based on the sampling signal, to obtain an internal select signal and an internal command signal; and a command decoder, where the command decoder is configured to decode the internal select signal and the internal command signal to obtain the data manipulation command.

In an embodiment of the first aspect of the present disclosure, the sampling signal includes a first sampling signal and a second sampling signal, where the first sampling signal and the second sampling signal are mutually inverting signals; and the internal command signal includes a first internal command signal obtained by sampling the internal command signal based on the first sampling signal, and a second internal command signal obtained by sampling the internal command signal based on the second sampling signal.

In an embodiment of the first aspect of the present disclosure, the first internal command signal and the second internal command signal are obtained by sampling within one cycle of the clock signal.

In an embodiment of the first aspect of the present disclosure, the latch includes: a first latch configured to receive the chip select signal to generate and output the internal select signal, where an output terminal of the first latch is connected to an input terminal of the command decoder; and a second latch configured to receive the chip select signal, where an output terminal of the second latch is disconnected.

In an embodiment of the first aspect of the present disclosure, the latch includes a plurality of third latches, where each of the plurality of third latches is configured to receive the first sampling signal and the command signal to generate a command bit of the first internal command signal, the command signals received by different ones of the plurality of third latches have different command bits, and output information from the plurality of third latches constitutes the first internal command signal. The first latch and the plurality of third latches are arranged along a same direction.

In an embodiment of the first aspect of the present disclosure, the latch includes a plurality of fourth latches, where each of the plurality of fourth latches is configured to receive the second sampling signal and the command signal to generate a command bit of the second internal command signal, the command signals received by different ones of the plurality of fourth latches have different command bits, and output information from the plurality of fourth latches constitute the first internal command signal. The second latch and the plurality of fourth latches are arranged along a same direction, where the first latch and the plurality of third latches are denoted as a first latch group, the second latch and the plurality of fourth latches are denoted as a second latch group, and the first latch group and the second latch group are arranged symmetrically.

In an embodiment of the first aspect of the present disclosure, the data processing circuit further includes a delay chain, where the delay chain is configured to receive the sampling signal and perform delay processing on the sampling signal to obtain a command clock signal. The command decoder is configured to decode based on the internal select signal, the internal command signal and the command clock signal to obtain the data manipulation command.

In an embodiment of the first aspect of the present disclosure, the delay chain includes a plurality of first inverters connected in sequence, and a total delay of the plurality of first inverters is equal to an inherent delay of the latch.

In an embodiment of the first aspect of the present disclosure, the command decoder includes: a logic circuit, where the logic circuit is configured to receive the internal select signal and the internal command signal, and decode the internal select signal and the internal command signal to obtain the data manipulation command; and a flip-flop connected to the logic circuit, where the flip-flop is configured to receive the data manipulation command and the command clock signal, and output the data manipulation command based on the command clock signal.

In an embodiment of the first aspect of the present disclosure, the receiver includes: a first buffer, where the first buffer is configured to buffer the clock signal to obtain the first sampling signal; and a second inverter, where the second inverter is configured to invert the first sampling signal to obtain the second sampling signal.

In an embodiment of the first aspect of the present disclosure, the processing circuit further includes a second buffer, which is configured to buffer the command signal and the chip select signal inputted through the input terminal.

In an embodiment of the first aspect of the present disclosure, the latch includes a D flip-flop.

A second aspect of the present disclosure provides a semiconductor device, which includes the data processing circuit according to any one of the embodiments in the first aspect of the present disclosure.

A third aspect of the present disclosure provides a data processing method, comprising: receiving a chip select signal and a plurality of command signals; obtaining a sampling signal based on a clock signal; sampling the chip select signal and the plurality of command signals based on the sampling signal to obtain an internal select signal and an internal command signal; and decoding the internal select signal and the internal command signal to obtain a data manipulation command. The sampling signal includes a first sampling signal and a second sampling signal, where the first sampling signal and the second sampling signal are mutually inverting signals. The internal command signal includes a first internal command signal obtained by sampling the internal command signal based on the first sampling signal, and a second internal command signal obtained by sampling the internal command signal based on the second sampling signal. The first internal command signal and the second internal command signal are obtained by sampling within one cycle of the clock signal.

In an embodiment of the third aspect of the present disclosure, the data processing method further includes: performing delay processing on the sampling signal to obtain a command clock signal.

In an embodiment of the third aspect of the present disclosure, the decoding the internal select signal and the internal command signal to obtain a data manipulation command includes: decoding based on the internal select signal, the internal command signal and the command clock signal to obtain the data manipulation command.

To sum up, the semiconductor device and data processing circuit and method provided by the embodiments of the present disclosure can receive the chip select signal and the plurality of command signals through the input terminal of the data processing circuit. After the receiver obtains the sampling signal based on the clock signal, the latch samples the chip select signal and the plurality of command signals based on the sampling signal to obtain the internal select signal and the internal command signal. Finally, the command decoder decodes the internal select signal and the internal command signal to obtain the data manipulation command. The semiconductor device and the data processing circuit and method provided by the embodiments can receive a complete command signal within one clock cycle, generate a data manipulation command and send the data manipulation command to a subsequent data manipulation circuit, such that the semiconductor device where the data processing circuit is positioned has higher processing speed, and thus processing efficiency of the semiconductor device can be improved.

### BRIEF DESCRIPTION OF THE DRAWINGS

To describe the technical solutions in the embodiments of the present disclosure or existing technologies more clearly, the accompanying drawings required for describing the embodiments or the existing technologies will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a semiconductor device according to an embodiment of the present disclosure;

FIG. 2 is a schematic time sequence diagram of a semiconductor device generating a data manipulation circuit provided by the present disclosure;

FIG. 3 is a schematic structural diagram of a data processing circuit provided by the present disclosure;

FIG. 4 is a schematic circuit structure diagram of a data processing circuit according to an embodiment of the present disclosure;

FIG. 5 is a schematic circuit structure diagram of a data processing circuit according to an embodiment of the present disclosure;

FIG. 6 is a schematic diagram showing a circuit structure of a command decoder in the data processing circuit provided by the present disclosure; and

FIG. 7 is a schematic diagram showing a processing sequence of the data processing circuit provided by the present disclosure.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by persons of ordinary skill in the art based on the embodiments of the present disclosure without creative efforts shall fall within the protection scope of the present disclosure.

In the specification, the claims and the foregoing accompanying drawings of the present disclosure, a term such as a first, a second, a third or a fourth (if present) is intended to distinguish between similar objects but is not necessarily intended to describe a particular sequence or precedence order. It is to be understood that data used like this may be interchangeable where appropriate, such that the embodiments of the present disclosure described herein can be implemented in sequences excluding those illustrated or described herein. Furthermore, terms such as “comprise”, “have” or other variants thereof are intended to cover a non-exclusive “comprise”, for example, processes, methods, systems, products or devices comprising a series of steps or units are not limited to these steps or units listed explicitly, but comprise other steps or units not listed explicitly, or other steps or units inherent to these processes, methods, systems, products or devices.

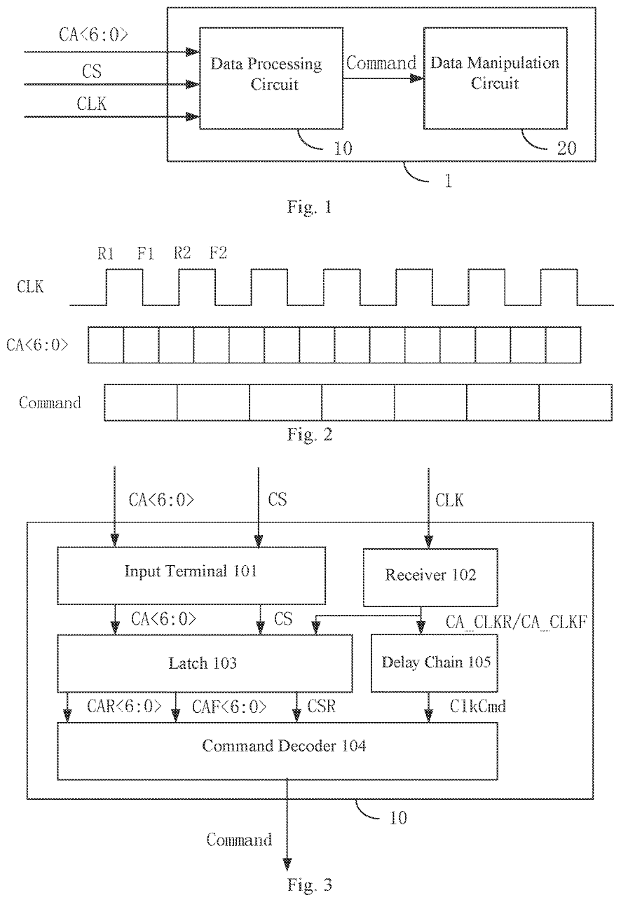

FIG. 1 is a schematic structural diagram of a semiconductor device provided by the present disclosure. The semiconductor device 1 as shown in FIG. 1 includes a data processing circuit 10 and a data manipulation circuit 20. The data processing circuit 10 may be configured to receive a command signal and a chip select signal inputted from outside of the semiconductor device, and decode the command signal and the chip select signal to generate a data manipulation command. Subsequently, the data processing circuit 10 sends the data manipulation command to the data manipulation circuit 20, such that the data manipulation circuit 20 performs a corresponding operation after receiving the data manipulation command.

In some embodiments, the semiconductor device shown in FIG. 1 may adopt a low power double data rate (LPDDR) standard, which may be an LPDDR5 standard.

In some embodiments, the data processing circuit receives a command signal and a chip select signal inputted within one cycle of a clock signal, and decodes the command signal and the chip select signal received to obtain the data manipulation command.

For example, FIG. 2 is a schematic time sequence diagram of the semiconductor device generating a data manipulation circuit provided by the present disclosure. As shown in FIG. 2, at a rising edge R1 of a clock signal CLK, the data processing circuit samples a command signal CA<6:0> to obtain a first internal command signal CAR<6:0>; and at a falling edge of the clock signal CLK, the data processing circuit samples the command signal CA<6:0> to obtain a second internal command signal CAF<6:0>. Subsequently, the data processing circuit decodes the first command signal CAR<6:0> and the second command signal CAF<6:0> to obtain a data manipulation command Command.

By analogy, in one cycle of each clock signal CLK, the data processing circuit 10 may sample the command signal CA<6:0> at the rising edge of the clock signal to obtain the first internal command signal CAR<6:0>, and sample the command signal CA<6:0> at the falling edge of the clock signal to obtain the second internal command signal CAF<6:0>. Subsequently, the data processing circuit 10 may decode the chip select signal, the first internal command signal CAR<6:0> and the second internal command signal CAF<6:0> to obtain the data manipulation command Command. Therefore, the data processing circuit 10 may receive a complete command signal, generate a data manipulation command and send the data manipulation command to the subsequent data manipulation circuit 10 within one cycle of the clock cycle, such that the semiconductor device has a higher processing speed, and processing efficiency of the semiconductor device can be improved.

Structures and principles of the data processing circuit provided by the embodiments of the present disclosure will be described in detail below with reference to embodiments. The embodiments provided by the present disclosure may be combined with each other, and the same or similar concepts or processes may not be repeated in some embodiments.

FIG. 3 is a schematic structural diagram of a data processing circuit provided by the present disclosure. The data processing circuit 10 as shown in FIG. 3 may be applied to the semiconductor device 1 as shown in FIG. 1, and the data processing circuit 10 is configured to decode, according to the received command signal, to obtain the data manipulation command.

In some embodiments, the data processing circuit 10 provided by the embodiment shown in FIG. 3 includes: an input terminal 101, a receiver 102, a latch 103, and a command decoder 104.

There may be a plurality of input terminals 101, and the plurality of input terminals 101 are respectively connected to the latch 103. The input terminal 101 is configured to receive the chip select signal CS or the command signal CA<6:0> and send them to the latch 103. The chip select signal CS or the command signal CA<6:0> may be configured to generate the data manipulation command Command. In some embodiments, one of the plurality of input terminals 101 may be configured to receive the chip select signal CS, and other input terminals 101 of the plurality of input terminals 101 may be configured to receive the command signal CA<6:0>, and the command signals CA<6:0> received by different input terminals 101 have different command bits.

An output terminal of the receiver 102 is connected to the latch 103. The receiver 102 is configured to receive the clock signal CLK, obtain a sampling signal based on the clock signal CLK, and send the sampling signal to the latch 103.

The latch 103 is connected to the output terminal of the receiver 102 and the plurality of input terminals 101. The latch 103 is configured to receive each command bit in the chip select signal CS and the command signal CR<6:0> sent by the input terminal 101. The latch 103 is also configured to receive the sampling signal sent by the receiver 102. The latch 103 samples the chip select signal CS and the command signal CR<6:0> based on the sampling signal to obtain an internal select signal CSR and an internal command signal, and sends the internal select signal CSR and the internal command signal to the command decoder 104. The internal command signal includes the first internal command signal CAR<6:0> and the second internal command signal CAF<6:0>.

The command decoder 104 is connected to the latch 103, and is configured to decode the internal select signal CSR, the first internal command signal CAR<6:0> and the second command signal CAF<6:0> to obtain the data manipulation command Command.

In some embodiments, the command decoder 104 may obtain, by means of table look-up from Command Truth Table, the data manipulation command Command corresponding to the internal select signal CSR, the first internal command signal CAR<6:0> and the second command signal CAF<6:0>. The data manipulation command Command includes: a data read operation command, a data write operation command, and a data refresh operation command, etc.

Finally, the command decoder 104 may send the data manipulation command Command to the data manipulation circuit 20, such that the data manipulation circuit 20 executes the data manipulation command Command to implement the corresponding data read operation, data write operation or data refresh operation, etc.

To sum up, in the data processing circuit provided in this embodiment, after the input terminal receives the chip select signal and the plurality of command signals, and after the receiver obtains the sampling signal based on the clock signal, the latch samples the chip select signal and the plurality of command signals based on the sampling signal to obtain the internal select signal and the internal command signal. Finally, the command decoder decodes the internal select signal and the internal command signal to obtain the data manipulation command. The data processing circuit provided in this embodiment may receive a complete command signal within one clock cycle, generate a data manipulation command and send the data manipulation command to a subsequent data manipulation circuit, such that the semiconductor device where the data processing circuit is positioned has higher processing speed, and thus processing efficiency of the semiconductor device can be improved.

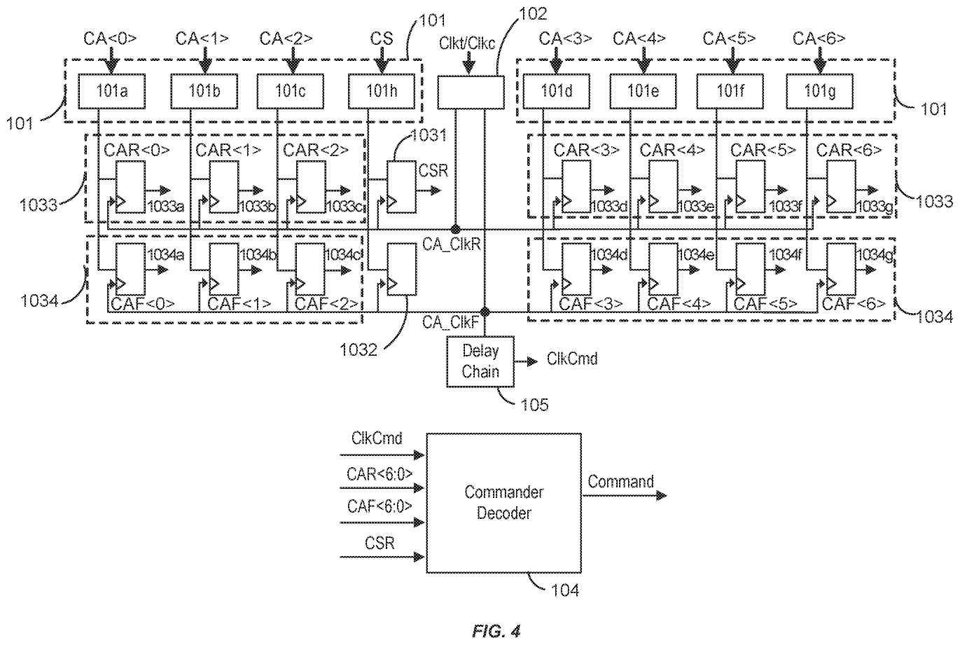

FIG. 4 is a schematic circuit structure diagram of a data processing circuit according to an embodiment of the present disclosure, and FIG. 4 shows a possible circuit structure of the data processing circuit 10 in FIG. 3.

As shown in FIG. 4, the plurality of input terminals 101 include different command bits configured for receiving the command signal CA<6:0>. For example, an input terminal 101a is configured to receive a bit CA<0> of the command signal CA<6:0>, an input terminal 101b is configured to receive a bit CA<1> of the command signal CA<6:0>, an input terminal 101c is configured to receive a bit CA<2> of the command signal CA<6:0>, an input terminal 101d is configured to receive a bit CA<3> of the command signal CA<6:0>, an input terminal 101e is configured to receive a bit CA<4> of the command signal CA<6:0>, an input terminal 101f is configured to receive a bit CA<5> of the command signal CA<6:0>, an input terminal 101g is configured to receive the bit CA<5> of the command signal CA<6:0>, and an input terminal 101h is configured to receive the chip select signal CS.

In some embodiments, the data processing circuit 10 further includes a plurality of second buffers. The plurality of second buffers are in one-to-one correspondence with the plurality of input terminals 101. Different command bits of the command signal CA<6:0> and the chip select signal CS are inputted into one second buffer respectively, and are buffered by the second buffer and then are outputted to the corresponding input terminal 101, which can improve drive capability of the command signal CA<6:0> and the chip select signal CS. In addition, it is to be understood that, when a signal is outputted through the input terminal 101, compared with the input, there is an inherent delay at the input terminal.

The receiver 102 is configured to receive the clock signal CLK. In the embodiment shown in FIG. 4, the clock signal may be a differential clock signal Clkt or Clkc of the semiconductor device.

In some embodiments, the receiver 102 includes: a first buffer and a second inverter. In some embodiments, the sampling signal includes a first sampling signal CA_ClkR and a second sampling signal CA_ClkF, and the first sampling signal CA_ClkR and the second sampling signal CA_ClkF are mutually inverting signals. The first buffer of the receiver 102 is configured to buffer the received clock signal CLK to obtain the first sampling signal CA_ClkR, and send the first sampling signal CA_ClkR to the latch 103 and the second inverter. The second inverter is configured to invert the first sampling signal CA_ClkR to obtain the second sampling signal CA_ClkF, and send the second sampling signal CA_ClkF to the latch 103.

The latch 103 includes a first latch 1031, a second latch 1032, a plurality of third latches 1033, and a plurality of fourth latches 1034. In some embodiments, each latch 103 may be a D flip-flop.

The first latch 1031 is configured to receive the first sampling signal CA_ClkR and the chip select signal CS, and generate the internal select signal CSR according to the first sampling signal CA_ClkR and the chip select signal CS. An output terminal of the first latch 1031 is connected to an output terminal of the command decoder 104, and may be configured to send the internal select signal CSR to the command decoder 104.

The second latch 1032 is configured to receive the second sampling signal CA_ClkF and the chip select signal CS, and an output terminal of the second latch 1032 is disconnected. The second latch 1032 may be configured to maintain to be symmetric with respect to the first latch 1031 in layout. In addition, it is to be noted that the data manipulation command Command obtained by decoding, such as the read operation, the write operation, is unconcerned with a result obtained by sampling the chip select signal CS by means of the second sampling signal CA_ClkF. Therefore, the output terminal of the second latch 1032 is disconnected here, which may also save power consumption.

The third latch 1033 is configured to receive the first sampling signal CA_ClkR and one command bit in the command signal CA<6:0>, and sample one command bit in the command signal CA<6:0> based on the first sampling signal CA_ClkR, to obtain one command bit in the first internal command signal CAR<6:0>. The first internal command signals CAR<6:0> received by different third latches 1033 have different command bits, and all command bits outputted by all the plurality of third latches 1033 constitute the first internal command signal CAR<6:0>.

For example, a third latch 1033a is configured to receive the first sampling signal CA_ClkR and the command bit CA<0> in the command signal CA<6:0>, and generate a command bit CAR<0> in the first internal command signal CAR<6:0>. A third latch 1033b is configured to receive the first sampling signal CA_ClkR and the command bit CA<1> in the command signal CA<6:0>, and generate a command bit CAR<1> in the first internal command signal CAR<6:0>. A third latch 1033c is configured to receive the first sampling signal CA_ClkR and the command bit CA<2> in the command signal CA<6:0>, and generate a command bit CAR<2> in the first internal command signal CAR<6:0>. A third latch 1033d is configured to receive the first sampling signal CA_ClkR and the command bit CA<3> in the command signal CA<6:0>, and generate a command bit CAR<3> in the first internal command signal CAR<6:0>. A third latch 1033e is configured to receive the first sampling signal CA_ClkR and the command bit CA<4> in the command signal CA<6:0>, and generate a command bit CAR<4> in the first internal command signal CAR<6:0>. A third latch 1033f is configured to receive the first sampling signal CA_ClkR and the command bit CA<5> in the command signal CA<6:0>, and generate a command bit CAR<5> in the first internal command signal CAR<6:0>. A third latch 1033g is configured to receive the first sampling signal CA_ClkR and the command bit CA<6> in the command signal CA<6:0>, and generate a command bit CAR<5> in the first internal command signal CAR<6:0>.

The fourth latch 1034 is configured to receive the second sampling signal CA_ClkF and one command bit in the command signal CA<6:0>, and sample one command bit in the command signal CA<6:0> based on the second sampling signal CA_ClkF, to obtain one command bit in the second internal command signal CAF<6:0>. The second internal command signals CAF<6:0> received by different fourth latches 1034 have different command bits, and all command bits outputted by all the plurality of fourth latches 1034 constitute the second internal command signal CAF<6:0>.

For example, a fourth latch 1034a is configured to receive the second sampling signal CA_ClkF and the command bit CA<0> in the command signal CA<6:0>, and generate a command bit CAF<0> in the second internal command signal CAF<6:0>. A fourth latch 1034b is configured to receive the second sampling signal CA_ClkF and the command bit CA<1> in the command signal CA<6:0>, and generate a command bit CAF<1> in the second internal command signal CAF<6:0>. A fourth latch 1034c is configured to receive the second sampling signal CA_ClkF and the command bit CA<2> in the command signal CA<6:0>, and generate a command bit CAF<2> in the second internal command signal CAF<6:0>. A fourth latch 1034d is configured to receive the second sampling signal CA_ClkF and the command bit CA<3> in the command signal CA<6:0>, and generate a command bit CAF<3> in the second internal command signal CAF<6:0>. A fourth latch 1034e is configured to receive the second sampling signal CA_ClkF and the command bit CA<4> in the command signal CA<6:0>, and generate a command bit CAF<4> in the second internal command signal CAF<6:0>. A fourth latch 1034f is configured to receive the second sampling signal CA_ClkF and the command bit CA<5> in the command signal CA<6:0>, and generate a command bit CAF<5> in the second internal command signal CAF<6:0>. A fourth latch 1034g is configured to receive the second sampling signal CA_ClkF and the command bit CA<6> in the command signal CA<6:0>, and generate a command bit CAF<6> in the second internal command signal CAF<6:0>.

In some embodiments, the first latch 1031 and the plurality of third latches 1033 are arranged in the same direction. In some embodiments, the second latch 1032 and the plurality of fourth latches 1034 are arranged in the same direction. The first latch 1031 and the plurality of third latches 1033 are denoted as a first latch group, the second latch 1032 and the plurality of fourth latches 1034 are denoted as a second latch group, and the first latch group and the second latch group are arranged symmetrically. Therefore, in the latch 103 provided in this embodiment, the second latch 1032 may be configured to correspond to the first latch 1031 in layout, allowing layouts of the data processing circuit 10 to be symmetrical, such that signal transmission lines in the data processing circuit 10 are symmetrical, which can maintain consistency of signal transmission timing sequence, and is beneficial to design and implementation of the data processing circuit 10. In addition, the design of this symmetrical arrangement can also simplify process steps in subsequent processes.

In some embodiments, the data processing circuit 10 further includes a delay chain 105, which is connected to the receiver 102 and the command decoder 104. The delay chain 105 may be configured to receive the sampling signal outputted from the receiver 102, process the sampling signal to obtain a command clock signal ClkCmd, and send the command clock signal ClkCmd to the command decoder 104. The command decoder 104 may decode based on the internal select signal CSR, the first internal command signal CAR<6:0>, the second command signal CAF<6:0> and the command clock signal ClkCmd, to obtain the data manipulation command Command.

In some embodiments, as shown in FIG. 4, the delay chain 105 may be configured to receive the second sampling signal CA_ClkF outputted from the receiver 102, and generate the command clock signal ClkCmd according to the second sampling signal CA_ClkF.

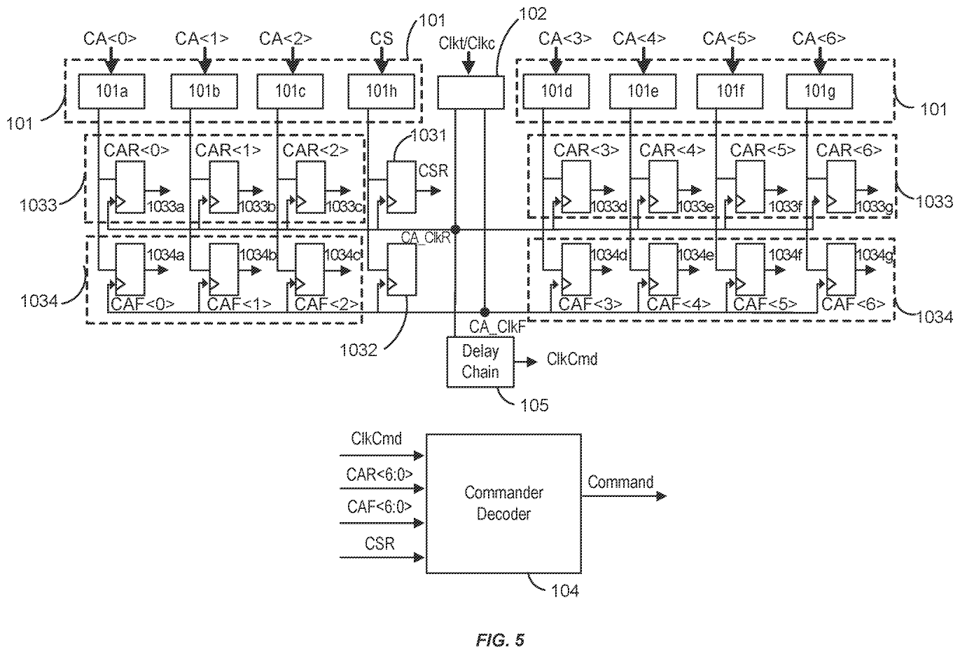

In some other embodiments, FIG. 5 is a schematic circuit structure diagram of a data processing circuit provided by the present disclosure. In the data processing circuit as shown in FIG. 5, the delay chain 105 may be configured to receive the first sampling signal CA_ClkR outputted from the receiver 102, and generate the command clock signal ClkCmd according to the first sampling signal CA_ClkR.

It is to be noted that differences between the data processing circuit shown in FIG. 5 and the data processing circuit shown in FIG. 4 is that the sampling signals received by the delay chain 105 are different, but the command clock signals ClkCmd generated is the same. In addition, other implementation manners and principles of the data processing circuit are the same as those in FIG. 4, and thus are not repeated here.

In some embodiments, the delay chain 105 may be a latch, which includes a plurality of first inverters connected in sequence. A total delay of the plurality of first inverters is equal to an inherent delay of the latch.

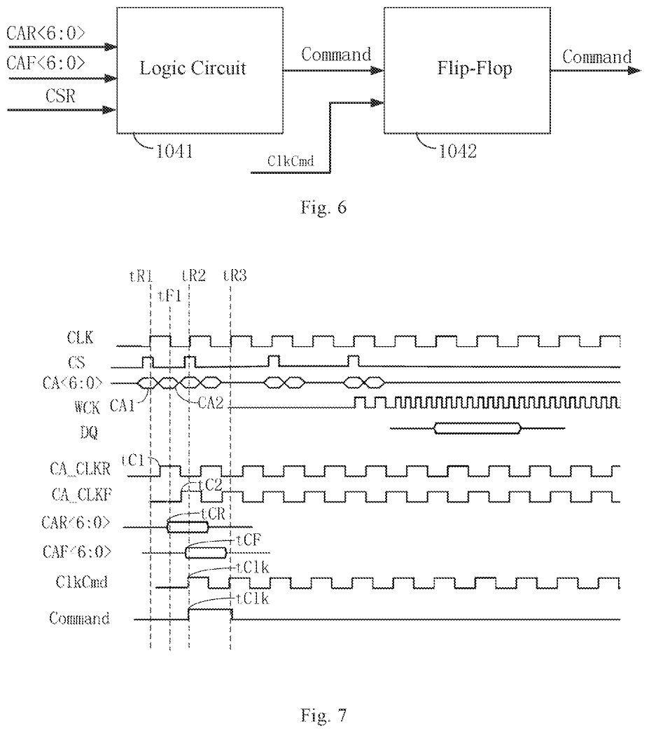

FIG. 6 is a schematic diagram showing a circuit structure of a command decoder in the data processing circuit provided by the present disclosure. As shown in FIG. 6, the command decoder 104 includes a logic circuit 1041 and a flip-flop 1042. An input terminal of the logic circuit 1041 is connected to the latch 103 and the delay chain 105. The logic circuit 1041 is configured to receive the internal select signal CSR, the first internal command signal CAR<6:0>, and the second command signal CAF<6:0>. Furthermore, the logic circuit 1041 is configured to decode according to the select signal CSR, the first internal command signal CAR<6:0> and the second command signal CAF<6:0> to obtain the data manipulation command Command, and send the data manipulation command Command to the flip-flop 1042. An input terminal of the flip-flop 1042 is connected to an output terminal of the logic circuit 1041. The flip-flop 1042 is configured to receive the data manipulation command Command and the command clock signal ClkCmd, and output the data manipulation command Command based on the command clock signal ClkCmd. In some embodiments, the flip-flop 1042 may be a D flip-flop.

FIG. 7 is a schematic diagram showing a processing sequence of the data processing circuit provided by the present disclosure. As shown in FIG. 7, the receiver 102 of the data processing circuit 10 is configured to receive the clock signal CLK. Moments of a first rising edge, a first falling edge and a second rising edge of the clock signal CLK are denoted as tR1, tF1, and tR2. In this case, duration between the moment tR1 of the first rising edge and the moment tR2 of the second rising edge is one clock cycle.

After the receiver 102 processes the clock signal CLK, the receiver 102 outputs the first sampling signal CA_ClkR and the second sampling signal CA_ClkF. The first sampling signal CA_ClkR is the buffered clock signal CLK. Taking the first rising edge of the clock signal CLK as an example, in the first sampling signal CA_ClkR, the moment tC1 of the first rising is later than the moment tR1 of the first rising edge in the clock signal CLK, and delay between tC1 and tR1 comes from the buffering process. The second sampling signal CA_ClkF is an inverting signal of the first sampling signal CA_ClkR. In the second sampling signal CA_ClkF, the moment tC2 of the first rising edge is later than the moment tR1 of the first rising edge of the clock signal CLK, and delay between tC2 and tC1 is half a cycle of the clock signal CLK.

The input terminal 101 of the data processing circuit 10 is configured to receive the command signal CA<6:0>, where, at the moment tR1 of the first rising edge of the clock signal CLK, the input terminal 101 of the data processing circuit 10 receives some command bits in the command signal CA<6:0> corresponding to the rising edge of the clock signal. At the moment tF1 of the first falling edge of the clock signal CLK, the input terminal 101 of the data processing circuit 10 receives some command bits in the command signal CA<6:0> corresponding to the falling edge of the clock signal. As can be seen, the data processing circuit 10 can complete the reception of all command bits in the command signal CA<6:0> within one clock cycle of the clock signal CLK.

An input terminal of the latch 103 is configured to receive the command signal CA<6:0> from the input terminal 101, the first sampling signal CA_ClkR and the second sampling signal CA_ClkF, and is configured to output the first internal command signal CAR<6:0> and the second internal command signal CAF<6:0> according to the first sampling signal CA_ClkR and the second sampling signal CA_ClkF.

Exemplarily, in combination with the timing sequence diagram shown in FIG. 7 and the circuit diagram shown in FIG. 4, the input terminal 101 may receive the command signal CA<6:0> at the moment tR1, and then, after the inherent delay of the input terminal, the plurality of third latches 1033 receive the command signal CA<6:0> outputted from the output terminal 101, and latch the command signal CA<6:0>. After receiving the first sampling signal CA_ClkR from the receiver 102 at the moment tC1, after a certain time delay, the plurality of third latches 1033 start to output the first internal command signal CAR<6:0> at the moment tCR.

The input terminal 101 may receive the chip select signal CS at the moment tR1, and then, after the inherent delay of the input terminal, the first latch 1031 receives the chip select signal CS outputted from the output terminal 101, and latches the chip select signal CS. After receiving the first sampling signal CA_ClkR from the receiver 102 at the moment tC1, after a certain time delay, the first latch 1031 starts to output the internal select signal CSR at the moment tCR.

At the moment tF1, the input terminal 101 receives the command signal CA<6:0>. Next, after the inherent delay of the input terminal, the fourth latch 1034 receives the command signal CA<6:0> outputted by the output terminal 101, and latches the command signal CA<6:0>. After receiving the second sampling signal CA_ClkF from the receiver at the moment tC2, after a certain time delay, the plurality of fourth latches 1034 start to output the second internal command signal CAF<6:0> at the moment tCF.

For the delay chain 105, in the circuit structure shown in FIG. 4, the delay chain 105 receives the first sampling signal CA_ClkR from the receiver 102 at the moment tC1, performs delay processing on the first sampling signal CA_ClkR, and then outputs the command clock signal ClkCmd at the moment tCLK. In the circuit structure shown in FIG. 5, the delay chain 105 receives the second sampling signal CA_ClkF from the receiver 102 at the moment tC2, and performs delay processing on the second sampling signal CA_ClkF, and then outputs the command clock signal ClkCmd at the moment tCLK. It is to be noted that for the delay processing of CA_ClkR and the delay processing of CA_ClkF, delay time of both may be set to be the same or different, as long as the data manipulation command Command can be outputted within one cycle of the clock signal CLK.

After the moment tCF, the command decoder 104 can receive the internal select signal CSR, the first internal command signal CAR<6:0> and the second internal command signal CAF<6:0> from the latch 103; and then the logic circuit 1041 in the command decoder 104 decodes to obtain the data manipulation command Command. Subsequently, the flip-flop 1042 in the command decoder 104 receives the command clock signal ClkCmd at the moment tCLK, and starts to output the data manipulation command Command at the moment tCLK.

As can be seen from the above process, the data processing circuit 10 can receive all command bits in the command signal CA<6:0> within one clock cycle between the moment tR1 and the moment tR2 of the clock signal CLK, generate the data manipulation command Command, and send the data manipulation command Command to the subsequent data manipulation circuit 20. Meanwhile, a time length for generating the data manipulation command Command may also be equal to one clock cycle of the clock signal CLK. Therefore, the semiconductor device 1 where the data processing circuit 10 is positioned has higher processing speed, and thus processing efficiency of the semiconductor device 1 can be improved.

Another embodiment of the present disclosure further provides a data processing method, which may be applied to the semiconductor device 1 as shown in FIG. 1 and may be executed by the data processing circuit 10. In some embodiments, the data processing method includes: receiving a chip select signal CS and a plurality of command signals CA<6:0>; obtaining a sampling signal based on a clock signal CLK, where the sampling signal includes a first sampling signal CA_ClkR and a second sampling signal CA_ClkF; sampling the chip select signal CS and the plurality of command signals CA<6:0> based on the first sampling signal CA_ClkR and the second sampling signal CA_ClkF to obtain an internal select signal CSR and an internal command signal; and decoding the internal select signal CSR and the internal command signal to obtain a data manipulation command Command.

In the data processing method provided by another embodiment of the present disclosure, the method further includes: performing delay processing on the first sampling signal CA_ClkR or the second sampling signal CA_ClkF to obtain a command clock signal ClkCmd. At this moment, the decoding the internal select signal CSR and the internal command signal to obtain a data manipulation command Command includes: decoding based on the internal select signal CSR, the internal command signal and the command clock signal ClkCmd to obtain the data manipulation command Command.

Those of ordinary skill in the art may understand that all or a part of steps in the above method embodiments may be implemented by program instruction related hardware. The foregoing program may be stored in a computer readable storage medium. When the program runs, the steps of the method embodiments are performed. The foregoing storage medium includes: any medium that can store program code, such as a ROM, a RAM, a magnetic disk, or an optical disc.

Finally, it is to be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A data processing circuit, comprising:
a plurality of input terminals, the plurality of input terminals being configured to receive a plurality of command signals or a chip select signal, the plurality of command signals received by different ones of the plurality of input terminals having different command bits;
a receiver configured to receive a clock signal and obtain a sampling signal based on the clock signal;
a latch connected to an output terminal of the receiver and the plurality of input terminals, the latch being configured to receive the chip select signal and the plurality of command signals, and sample the chip select signal and the plurality of command signals based on the sampling signal, to obtain an internal select signal and an internal command signal; and
a command decoder, the command decoder being configured to decode the internal select signal and the internal command signal to obtain the data manipulation command.

2. The circuit according to claim 1, comprising
the sampling signal comprising a first sampling signal and a second sampling signal, the first sampling signal and the second sampling signal being mutually inverting signals, and the internal command signal comprising a first internal command signal obtained by sampling the internal command signal based on the first sampling signal, and a second internal command signal obtained by sampling the internal command signal based on the second sampling signal.

3. The circuit according to claim 2, wherein
the first internal command signal and the second internal command signal are obtained by sampling within one cycle of the clock signal.

4. The circuit according to claim 3, wherein the latch comprises:
a first latch configured to receive the first sampling signal and the chip select signal to generate and output the internal select signal, an output terminal of the first latch being connected to an input terminal of the command decoder; and
a second latch configured to receive the second sampling signal and the chip select signal, an output terminal of the second latch being disconnected.

5. The circuit according to claim 4, wherein the latch comprises a plurality of third latches, each of the plurality of third latches being configured to receive the first sampling signal and the command signal to generate a command bit of the first internal command signal, the command signals received by different ones of the plurality of third latches having different command bits, and output information from the plurality of third latches constituting the first internal command signal; and
the first latch and the plurality of third latches are arranged along a same direction.

6. The circuit according to claim 5, wherein
the latch comprises a plurality of fourth latches, each of the plurality of fourth latches being configured to receive the second sampling signal and the command signal to generate a command bit of the second internal command signal, the command signals received by different ones of the plurality of fourth latches having different command bits, and output information from the plurality of fourth latches constituting the first internal command signal; and
the second latch and the plurality of fourth latches are arranged along a same direction, the first latch and the plurality of third latches being denoted as a first latch group, the second latch and the plurality of fourth latches being denoted as a second latch group, and the first latch group and the second latch group being arranged symmetrically.

7. The circuit according to claim 1, further comprising:
a delay chain, the delay chain being configured to receive the sampling signal and perform delay processing on the sampling signal to obtain a command clock signal, the command decoder being configured to decode based on the internal select signal, the internal command signal and the command clock signal to obtain the data manipulation command.

8. The circuit according to claim 7, wherein the delay chain comprises a plurality of first inverters connected in sequence, a total delay of the plurality of first inverters being equal to an inherent delay of the latch.

9. The circuit according to claim 7, wherein the command decoder comprises:
a logic circuit, the logic circuit being configured to receive the internal select signal and the internal command signal, and decode the internal select signal and the internal command signal to obtain the data manipulation command; and
a flip-flop connected to the logic circuit, the flip-flop being configured to receive the data manipulation command and the command clock signal, and output the data manipulation command based on the command clock signal.

10. The circuit according to claim 2, wherein the receiver comprises:
a first buffer, the first buffer being configured to buffer the clock signal to obtain the first sampling signal; and
a second inverter, the second inverter being configured to invert the first sampling signal to obtain the second sampling signal.

11. The circuit according to claim 1, further comprising:
a second buffer configured to buffer the command signal and the chip select signal inputted through the input terminal.

12. The circuit according to claim 1, wherein the latch comprises a D flip-flop.

13. A semiconductor device, comprising the data processing circuit according to claim 1.

14. A data processing method, comprising:
receiving a chip select signal and a plurality of command signals;
obtaining a sampling signal based on a clock signal, the sampling signal comprising a first sampling signal and a second sampling signal, and the first sampling signal and the second sampling signal being mutually inverting signals;
sampling the chip select signal and the plurality of command signals based on the sampling signal to obtain an internal select signal and an internal command signal; the internal command signal comprising a first internal command signal obtained by sampling the internal command signal based on the first sampling signal, and a second internal command signal obtained by sampling the internal command signal based on the second sampling signal; the first internal command signal and the second internal command signal being obtained by sampling within one cycle of the clock signal; and
decoding the internal select signal and the internal command signal to obtain a data manipulation command.

15. The method according to claim 14, further comprising:
performing delay processing on the sampling signal to obtain a command clock signal; wherein
the decoding the internal select signal and the internal command signal to obtain a data manipulation command comprises:
decoding based on the internal select signal, the internal command signal and the command clock signal to obtain the data manipulation command.
